(19) United States
(12) Patent Application Publication
(10) Pub. No.: US 2025/0301690 A1
(43) Pub. Date: Sep. 25, 2025

(54) HIGH-SIDE SWITCH DEVICE HAVING SPLIT GATES AND MANUFACTURING METHOD THEREOF

(71) Applicant: Richtek Technology Corporation, Zhubei City (TW)

(72) Inventors: Han-Chung Tai, Hsinchu (TW); Kuo-Hsuan Lo, Taoyuan (TW)

(21) Appl. No.: 18/817,052

(22) Filed: Aug. 27, 2024

Related U.S. Application Data
(60) Provisional application No. 63/567,923, filed on Mar. 20, 2024.

(30) Foreign Application Priority Data
Jul. 30, 2024 (TW) 113128235

(51) Int. Cl. H01L 29/78; H01L 25/07; H01L 27/088; H01L 29/08; H01L 29/66

(52) U.S. Cl. CPC H10D 30/611; H01L 25/072; H10D 30/023; H10D 62/149; H10D 84/83

(57) ABSTRACT

The present invention provides a high-side switch device having split gates. The high-side switch device includes: at least one tie-gate high-side switch device, each having a split gate independently connected to a gate; and at least one tie-source high-side switch device, each having a split gate independently connected to a source. The at least one tie-gate high-side switch device and the at least one tie-source high-side switch device are electrically connected in parallel. The quantity ratio of the at least one tie-gate high-side switch device to the at least one tie-source high-side switch device can be adjusted to modulate the Miller capacitance of the high-side switch device having split gates.

### CROSS REFERENCE

The present invention claims priority to U.S. 63/567923 filed on Mar. 20, 2024, and claims priority to TW 113128235 filed on Jul. 30, 2024.

### BACKGROUND OF THE INVENTION

### Field of Invention

The present invention relates to a high-side switch device having split gates and a manufacturing method thereof. In particular, it relates to such high-side switch device in which a quantity ratio of tie-gate high-side switch devices to tie-source high-side switch devices can be adjusted to modulate the Miller capacitance, as well as the manufacturing method such a device.

### Description of Related Art

In the development of power converters, as power efficiency becomes increasingly important, faster switching speeds have become necessary to reduce losses. However, with the increase in switching speed, certain negative effects arise, such as increased electromagnetic interference (EMI). In buck converters, fast-switching field-effect transistors (FETs) may exhibit significant voltage overshoot and ringing effects at the phase node. The magnitude of the ringing is proportional to the switching speed of the high-side MOSFET and the parasitic inductance in the FET package.

FIG. 1 shows a schematic diagram of a typical buck converter circuit. As shown in FIG. 1, the buck converter 1 includes a high-side switch device Q1, a low-side switch device Q2, and an inductor L. Parasitic elements such as equivalent series inductance (ESL) and equivalent series resistance (ESR) exist between the input voltage Vin and the reference ground potential PGND. The equivalent series inductance is represented by inductors L1, L2, L3, and L4. According to the inductance formula V=L*di/dt, the ESL causes a ringing effect in the phase node voltage Vsw. During the process of converting the input voltage Vin to the output voltage Vout in the buck converter, this ringing effect results in additional power loss.

In the prior art, to improve power efficiency, circuit designers have attempted to reduce switching losses by increasing the switching frequency. However, this leads to higher voltage overshoot and ringing, which increases electromagnetic interference (EMI), thereby affecting the stability and performance of the system.

In view of the above, the present invention proposes high-side switch device having split gates and a manufacturing method thereof, which adopt appropriate layout design techniques to control ringing and overshoot, and ensure that the FET operates below absolute maximum voltage rating. By controlling the ringing within the absolute maximum rating of the FET, optimal switching speed and conversion efficiency can be achieved while avoiding voltage overshoot.

### SUMMARY OF THE INVENTION

From one perspective, the present invention provides a high-side switch device having split gates, comprising:
at least one tie-gate high-side switch device, each having a split gate independently connected to a corresponding gate; and at least one tie-source high-side switch device, each having a split gate independently connected to a corresponding source; wherein the at least one tie-gate high-side switch device and the at least one tie-source high-side switch device are electrically connected in parallel; wherein a ratio of a quantity of the at least one tie-gate high-side switch device to a quantity of the at least one tie-source high-side switch device is selectable to adjust a Miller capacitance of the high-side switch device having split gates.

In one embodiment, the ratio of the quantity of the at least one tie-gate high-side switch device to the quantity of the at least one tie-source high-side switch device is adjusted according to a peak voltage of a ringing at a phase node and a switching speed during a normal operation.

In one embodiment, the ratio of the quantity of the at least one tie-gate high-side switch device to the quantity of the at least one tie-source high-side switch device is further adjusted according to a power conversion efficiency during the normal operation.

In one embodiment, each of the at least one tie-gate high-side switch device or each of the at least one tie-source high-side switch device includes: a semiconductor layer formed on a substrate and having a top surface and a bottom surface opposite to the top surface in a vertical direction; a first high-voltage well region of a first conductivity type formed in the semiconductor layer and connected to the top surface in the vertical direction; a body region of a second conductivity type formed in the first high-voltage well region and connected to the top surface in the vertical direction; the gate formed on the top surface of the semiconductor layer, wherein a portion of the body region is located right below and in contact with the gate in the vertical direction to provide an inversion current path in a conductive operation of the tie-gate high-side switch device or the tie-source high-side switch device; a resist protection oxide (RPO) region formed on the top surface, with a portion of the resist protection oxide region being connected to the top surface and located above a drift region; the split gate formed on the resist protection oxide region and arranged parallel to the gate in a width direction; and a source and a drain of the first conductivity type formed in the semiconductor layer beneath and in contact with the top surface, wherein the source is located in the body region under an outer side of the gate and the drain is located in the first high-voltage well region under another outer side of the gate remote from the body region, wherein the drift region is located between the drain and the body region in a channel direction and located in the first high-voltage well region close to the top surface to serve as a drift current path in the conductive operation of the tie-gate high-side switch device or the tie-source high-side switch device.

In one embodiment, each of the at least one tie-gate high-side switch device or each of the at least one tie-source high-side switch device further includes: a first deep well region of the second conductivity type formed in the semiconductor layer and located beneath and in contact with the first high-voltage well region in the vertical direction; a second deep well region of the first conductivity type formed in the semiconductor layer and located beneath and in contact with the first deep well region in the vertical direction; and a buried layer of the first conductivity type formed beneath the second deep well region and connected to the second deep well region in the vertical direction, the buried layer entirely covering an underside of the second deep well region, with portions of the buried layer being located in the substrate and in the semiconductor layer on both sides of an interface between the substrate and the semiconductor layer in the vertical direction; wherein the first deep well region is located between the first high-voltage well region and the second deep well region in the vertical direction, forming a complete isolation structure during a normal operation.

From another perspective, the present invention provides a manufacturing method of a high-side switch device having split gates, comprising: forming at least one tie-gate high-side switch device, each having a split gate independently connected to a corresponding gate; and forming at least one tie-source high-side switch device, each having a split gate independently connected to a corresponding source; wherein the at least one tie-gate high-side switch device and the at least one tie-source high-side switch device are electrically connected in parallel; wherein a ratio of a quantity of the at least one tie-gate high-side switch device to a quantity of the at least one tie-source high-side switch device is selectable to adjust a Miller capacitance of the high-side switch device having split gates.

In one embodiment, the step of forming each of the at least one tie-gate high-side switch device or each of the at least one tie-source high-side switch device includes: forming a semiconductor layer on a substrate, the semiconductor layer having a top surface and a bottom surface opposite to the top surface in a vertical direction; forming a first high-voltage well region in the semiconductor layer, the first high-voltage well region having a first conductivity type, and being connected to the top surface in the vertical direction; forming a body region in the first high-voltage well region, the body region having a second conductivity type, and being connected to the top surface in the vertical direction; forming the gate on the top surface of the semiconductor layer, wherein a portion of the body region is located right below and in contact with the gate in the vertical direction to provide an inversion current path in a conductive operation of the tie-gate high-side switch device or the tie-source high-side switch device; forming a resist protection oxide (RPO) region on the top surface, with a portion of the resist protection oxide region being connected to the top surface and located above a drift region; forming the split gate on the resist protection oxide region, with the split gate arranged parallel to the gate in a width direction; and forming a source and a drain beneath and in contact with the top surface in the semiconductor layer, the source and the drain having the first conductivity type, wherein the source is located in the body region under an outer side of the gate and the drain is located in the first high-voltage well region under another outer side of the gate remote from the body region, wherein the drift region is located between the drain and the body region in a channel direction and located in the first high-voltage well region close to the top surface to serve as a drift current path in the conductive operation of the tie-gate high-side switch device or the tie-source high-side switch device.

In one embodiment, the step of forming each of the at least one tie-gate high-side switch device or the at least one tie-source high-side switch device further comprises: forming a first deep well region in the semiconductor layer, the first deep well region having the second conductivity type, and being located beneath and in contact with the first high-voltage well region in the vertical direction; forming a second deep well region in the semiconductor layer, the second deep well region having the first conductivity type, and being located beneath and in contact with the first deep well region in the vertical direction; and forming a buried layer beneath the second deep well region, the buried layer having the first conductivity type, and being connected to the second deep well region in the vertical direction, the buried layer entirely covering an underside of the second deep well region, with portions of the buried layer being located in the substrate and in the semiconductor layer on both sides of an interface between the substrate and the semiconductor layer in the vertical direction; wherein the first deep well region is located between the first high-voltage well region and the second deep well region in the vertical direction, forming a complete isolation structure during a normal operation.

The objectives, technical details, features, and effects of the present invention will be better understood with regard to the detailed description of the embodiments below, with reference to the attached drawings.

### BRIEF DESCRIPTION OF THE DRAWINGS

FIG. 1 is a schematic of a typical buck converter circuit.

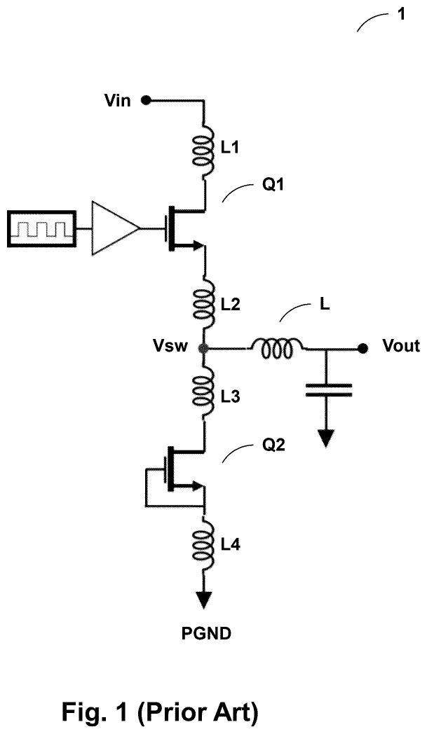

FIG. 2 is a top view schematic diagram showing a high-side switch device having split gates according to an embodiment of the present invention.

FIG. 3 is a cross-sectional schematic diagram showing a tie-gate high-side switch device according to an embodiment of the present invention.

FIG. 4 is a cross-sectional schematic diagram showing a tie-source high-side switch device according to an embodiment of the present invention.

FIG. 5 is a cross-sectional schematic diagram showing a high-side switch device having split gates according to an embodiment of the present invention.

FIG. 6 is a cross-sectional schematic diagram showing a tie-gate high-side switch device according to an embodiment of the present invention.

FIG. 7 is a cross-sectional schematic diagram showing a tie-source high-side switch device according to an embodiment of the present invention.

FIG. 8 shows signal waveforms of the phase node voltage Vsw at different ratios of tie-gate high-side switch devices to tie-source high-side switch devices.

FIG. 9 shows signal waveforms of the gate voltage Vg and the drain voltage Vd at different ratios of tie-gate high-side switch devices to tie-source high-side switch devices.

FIGS. 10A-10F are cross-sectional schematic diagrams showing the manufacturing method of a tie-gate high-side switch device according to an embodiment of the present invention.

### DESCRIPTION OF THE PREFERRED EMBODIMENTS

The drawings as referred to throughout the description of the present invention are for illustration only, to show the interrelations among the process steps and the layers, while the shapes, thicknesses, and widths are not drawn in actual scale.

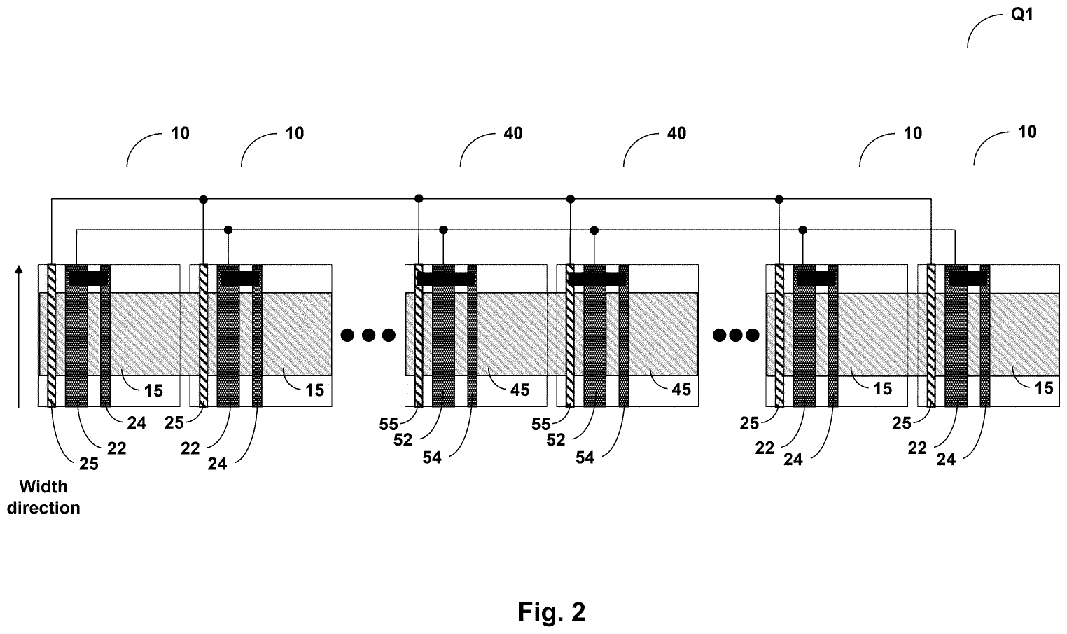

FIG. 2 is a top view schematic diagram of a high-side switch device having split gates according to an embodiment of the present invention. As shown in FIG. 2, the high-side switch device Q1 includes a plurality of tie-gate high-side switch devices 10 and a plurality of tie-source high-side switch devices 40. These tie-gate high-side switch devices 10 and tie-source high-side switch devices 40 are electrically connected in parallel and arranged in a finger structure. Each split gate 24 of the tie-gate high-side switch device 10 is independently connected to a corresponding gate 22, which is within the same tie-gate high-side switch device 10. Similarly, each split gate 54 of the tie-source high-side switch device 40 is independently connected to a corresponding source 55, which is within the same tie-source high-side switch device 40. A ratio of a quantity of the tie-gate high-side switch devices 10 to a quantity of tie-source high-side switch devices 40 is selectable and can be selected to adjust a Miller capacitance of the high-side switch device Q1.

According to the present invention, Miller capacitance modulation is achieved by appropriately selecting the layout of the tie-gate high-side switch devices 10 and the tie-source high-side switch devices 40. Simulation results show that a larger Miller capacitance will slow down the switching speed of the high-side switch device Q1 with split gates and significantly reduce voltage ringing at a phase node.

In one embodiment, the ratio of the number of tie-gate high-side switch devices 10 to the number of tie-source high-side switch devices 40 is adjusted based on the ringing voltage at the phase node and the switching speed required by the user during normal operation.

In another embodiment, the ratio of the number of tie-gate high-side switch devices 10 to the number of tie-source high-side switch devices 40 is further adjusted based on the power conversion efficiency during normal operation.

It should be noted that in this embodiment, the number of tie-gate high-side switch devices 10 and the number of tie-source high-side switch devices 40 are both plural, but their respective numbers can also be as low as one.

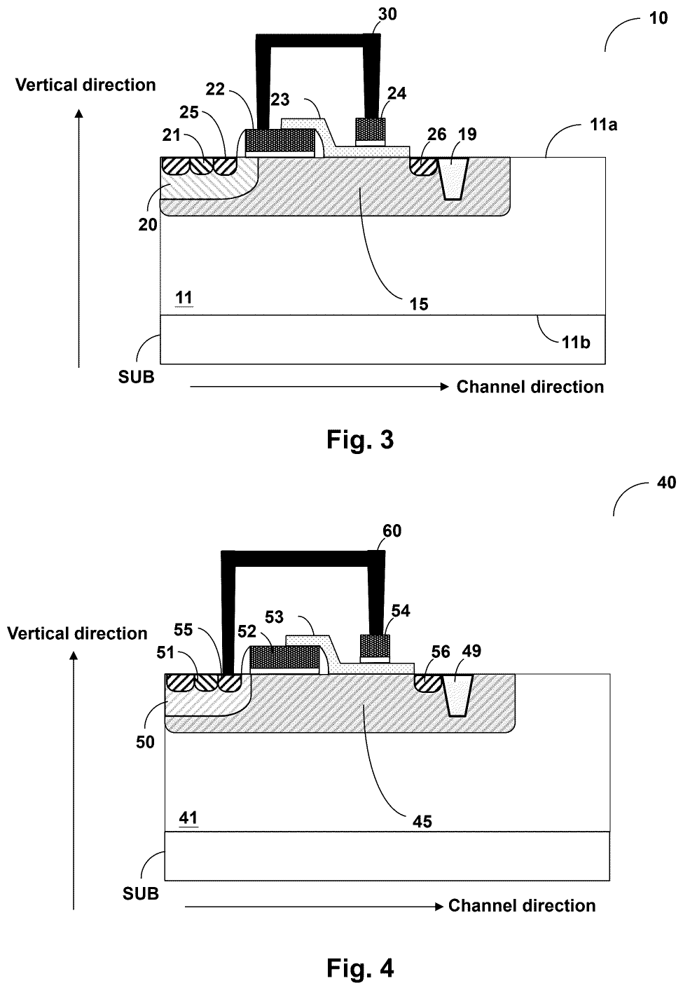

FIG. 3 is a cross-sectional schematic diagram of a tie-gate high-side switch device according to an embodiment of the present invention. As shown in FIG. 3, the tie-gate high-side switch device 10 includes a semiconductor layer 11, a first high-voltage well region 15, an isolation region 19, a body region 20, a body contact 21, a gate 22, a resist protection oxide (RPO) region 23, a split gate 24, a source 25, a drain 26, and an independent connection channel 30.

Still referring to FIG. 3, the semiconductor layer 11 is formed on a substrate SUB and has a top surface 11a and a bottom surface 11b opposite to the top surface 11a in the vertical direction. The first high-voltage well region 15 of a first conductivity type is formed in the semiconductor layer 11, and in the vertical direction, the first high-voltage well region 15 is located below and connected to the top surface 11a. The body region 20 of a second conductivity type is formed in the first high-voltage well region 15, and in the vertical direction, the body region 20 is located below and connected to the top surface 11a.

It should be noted that the substrate 11, for example, but not limited to, is a P-type or N-type semiconductor substrate. The first and second conductivity types are of opposite electrical properties; for instance, when the first conductivity type is P-type, the second conductivity type is N-type, and vice versa.

The gate 22 is formed on the top surface 11a of the semiconductor layer 11. In the vertical direction, a portion of the body region 20 is located right below and in contact with the gate 22 to provide an inversion current path in the conductive operation of the tie-gate high-side switch device 10. The resist protection oxide region 23 is formed on the top surface 11a, with a portion connected to the top surface 11a and located above a drift region. The split gate 24 is formed on the resist protection oxide region 23 and arranged parallel to the gate 22 in the width direction (as schematically shown in FIG. 2). The source 25 and drain 26 of the first conductivity type are formed beneath the top surface 11a and connected to the top surface 11a in the vertical direction. The source 25 is located in the body region 20 under an outer side of the gate 22, while the drain 26 is located in the first high-voltage well region 15 under another outer side of the gate remote from the body region 20. In the channel direction, the drift region is located between the drain 26 and the body region 20, close to the top surface 11a in the first high-voltage well region 15, serving as a drift current path during the conductive operation of the tie-gate high-side switch device 10. Note that the conductive operation indicates that the corresponding device is turned ON as well-known to those skilled in the art.

The isolation region 19 is formed in the semiconductor layer 11 to electrically isolate the tie-gate high-side switch device from adjacent devices. The isolation region 19 may be, but is not limited to, a shallow trench isolation (STI) structure as shown in FIG. 3. The body contact 21 is formed beneath and connected to the top surface 11a, located in the body region 20, serving as an electrical contact for the body region 20. In this embodiment, the body contact 21 is connected to the source 25, sharing the same potential.

The independent connection channel 30 is formed to independently connect the split gate 24 and the gate 22 to electrically connect the split gate 24 to the gate 22. Each tie-gate high-side switch device 10 includes its own independent connection channel 30, which is not shared with other tie-gate high-side switch devices 10. The independent connection channel 30 may be formed by process steps of forming plugs and metal lines, which are well-known to those skilled in the art and are not further detailed here.

It should be noted that the gate 22 includes a conductive layer, a dielectric layer connected to the top surface 11a, and a spacer covering the sidewalls of the conductive layer with electrical insulation properties, which are well-known to those skilled in the art and are not further detailed here. It should be noted that the width direction refers to the direction into the plane of the figure, perpendicular to both the channel direction and the vertical direction.

It should be noted that the so-called drift current path refers to the area through which conduction current flows in a drift manner during the conductive operation of a power device (including tie-gate high-side switch devices and tie-source high-side switch devices), which is well-known to those skilled in the art and is not further detailed here. It should be noted that the top surface 11a does not refer to a perfectly flat plane but to a surface of the semiconductor layer 11.

It should be noted that the independent connection channel 30 in FIG. 3 schematically shows the connection between the split gate 24 and the gate 22. In the width direction, the independent connection channel 30 is located outside the drift current path, which means it is outside the first high-voltage well region 15. In other words, the independent connection channel 30 does not appear in the same tangential cross-section as the first high-voltage well region 15, and this applies to the following cross-sectional schematic diagrams as well.

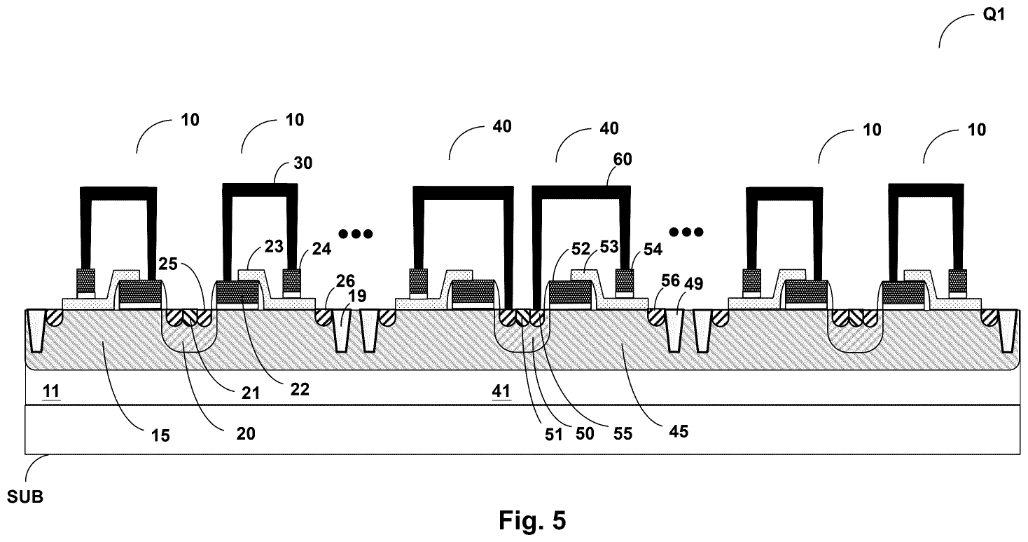

FIG. 4 is a cross-sectional schematic diagram of a tie-source high-side switch device according to an embodiment of the present invention. As shown in FIG. 4, the tie-source high-side switch device 40 includes a semiconductor layer 41, a first high-voltage well region 45, an isolation region 49, a body region 50, a body contact 51, a gate 52, a resist protection oxide region 53, a source 55, a drain 56, and an independent connection channel 60. Except for the independent connection channel 60, the tie-source high-side switch device 40 shown in FIG. 4 is structurally identical to the tie-gate high-side switch device 10 shown in FIG. 3, and thus will not be further described. The independent connection channel 60 is formed to independently connect the split gate 54 and the source 55 to electrically connect the split gate 54 to the source 55. Each tie-source high-side switch device 40 includes its own independent connection channel 60, which is not shared with other tie-source high-side switch devices 40. The independent connection channel 60 may be formed by process steps of forming plugs and metal lines, which are well-known to those skilled in the art and are not further detailed here.

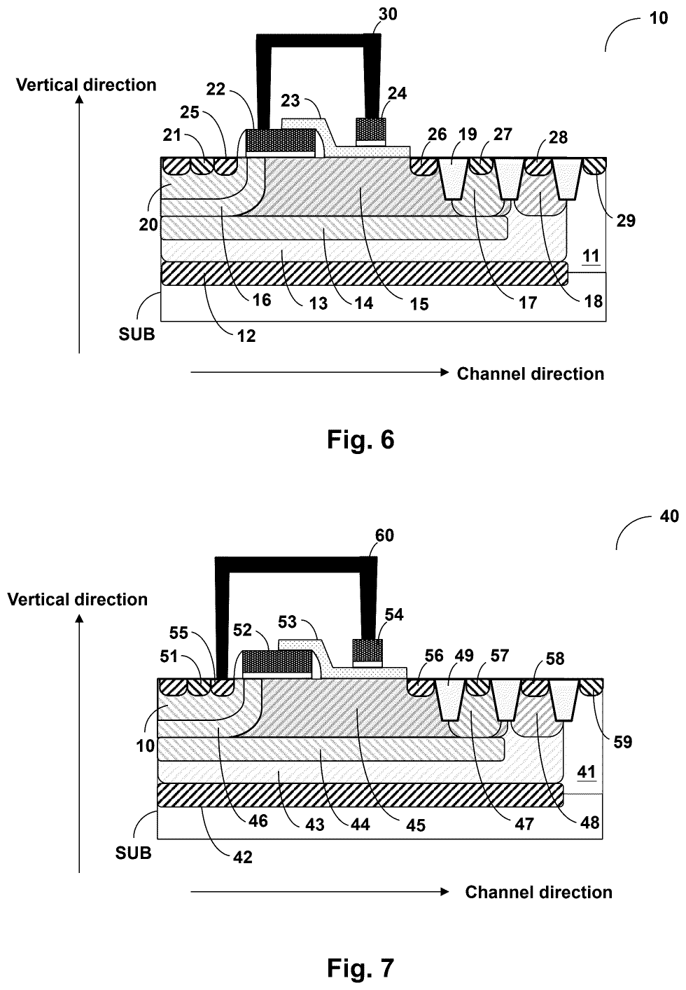

FIG. 5 is a cross-sectional schematic diagram of a high-side switch device having split gates according to an embodiment of the present invention. FIG. 5 is a cross-sectional schematic diagram of the high-side switch device Q1 as shown in FIG. 2. As shown in FIG. 5, all the tie-gate high-side switch devices 10 and all the tie-source high-side switch devices 40 in the high-side switch device Q1 share the same substrate SUB, the same semiconductor layer (semiconductor layers 11 and 41 are the same semiconductor layer), and the same first high-voltage well region (the first high-voltage well regions 15 and 45 are the same first high-voltage well region). The tie-gate high-side switch device 10 shares the same body region 20 with the adjacent tie-gate high-side switch device 10. The tie-source high-side switch device 40 shares the same body region 20 with the adjacent tie-source high-side switch device 40. If the device adjacent to the tie-gate high-side switch device 10 is a tie-source high-side switch device 40, the tie-gate high-side switch device 10 can also share the same body region 20 (or 50) with the adjacent tie-source high-side switch device 40. Similarly, the tie-source high-side switch device 40 can also share the same body region 50 (or 20) with the adjacent tie-gate high-side switch device 10.

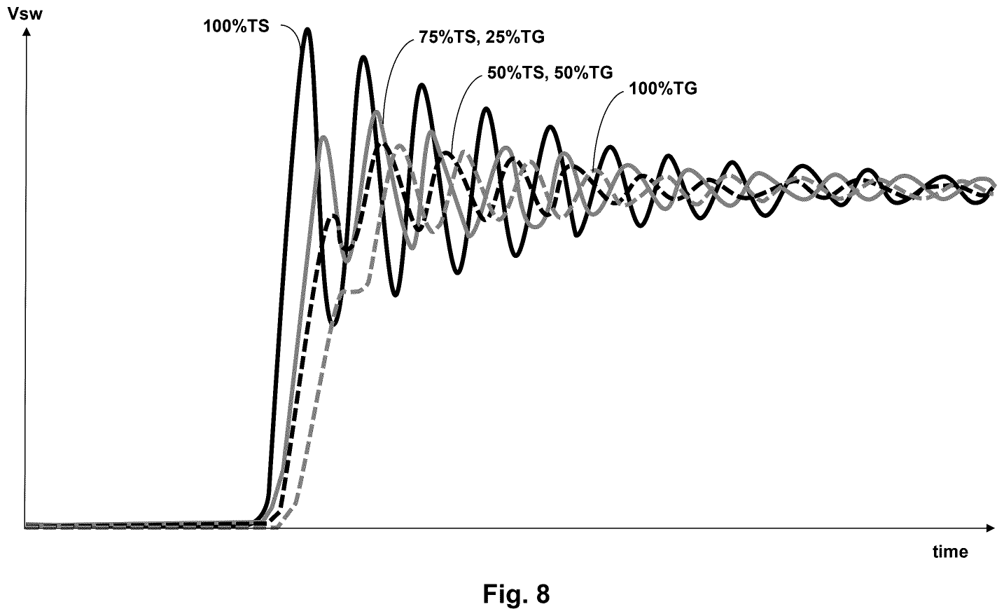

FIG. 6 is a cross-sectional schematic diagram of another tie-gate high-side switch device according to an embodiment of the present invention. As shown in FIG. 6, in addition to the semiconductor layer 11, the first high-voltage well region 15, the isolation region 19, the body region 20, the body contact 21, the gate 22, the resist protection oxide region 23, the split gate 24, the source 25, the drain 26, and the independent connection channel 30 shown in FIG. 3, the tie-gate high-side switch device 10 also includes, for example, a first deep well region 14, second high-voltage well regions 16 and 17, a second deep well region 13, a buried layer 12, a third high-voltage well region 18, and electrical contact regions 27, 28, and 29.

The first deep well region 14 of the second conductivity type is formed in the semiconductor layer 11, and in the vertical direction, the first deep well region 14 is located below and connected to the first high-voltage well region 15. The second deep well region 13 of the first conductivity type is formed in the semiconductor layer 11, and in the vertical direction, the second deep well region 13 is located below and connected to the first deep well region 14. The first deep well region 14 separates the first high-voltage well region 15 from the second deep well region 13 to form a fully-isolated structure. The second high-voltage well regions 16 and 17 of the first conductivity type are formed in the first high-voltage well region 15. In the vertical direction, the second high-voltage well region 16 is located beneath and connected to the body region 20, while the second high-voltage well region 17 is formed beneath and connected to the top surface 11a. The second high-voltage well regions 16 and 17 are both located above and connected to the first deep well region 14. The second high-voltage well region 16 serves as an extension region of the body region 20, and the second high-voltage well region 17 serves as an electrical connection channel for the first deep well region 14. Through the electrical contact region 27, the first deep well region 14 can be electrically connected to the exterior of the tie-gate high-side switch device 10.

The buried layer 12 of the first conductivity type is formed below and connected to the second deep well region 13 in the vertical direction, completely covering the underside of the second deep well region 13. In the vertical direction, the buried layer 12 is, for example, formed on both sides of the interface between the substrate SUB and the semiconductor layer 11, with portions of the buried layer 12 located in the substrate SUB and portions located in the semiconductor layer 11. The third high-voltage well region 18 is formed beneath and connected to the top surface 11a. The third high-voltage well region 18 is located above and connected to the second deep well region 13, serving as an electrical connection channel for the second deep well region 13. Through the electrical contact region 28, the second deep well region 13 can be electrically connected to the exterior of the tie-gate high-side switch device 10. The electrical contact regions 27, 28, and 29 all serve as electrical contacts. The electrical contact region 27 serves as the electrical contact for the second high-voltage well region 17; the electrical contact region 28 serves as the electrical contact for the third high-voltage well region 18; and the electrical contact region 29 serves as the electrical contact for the semiconductor layer 11.

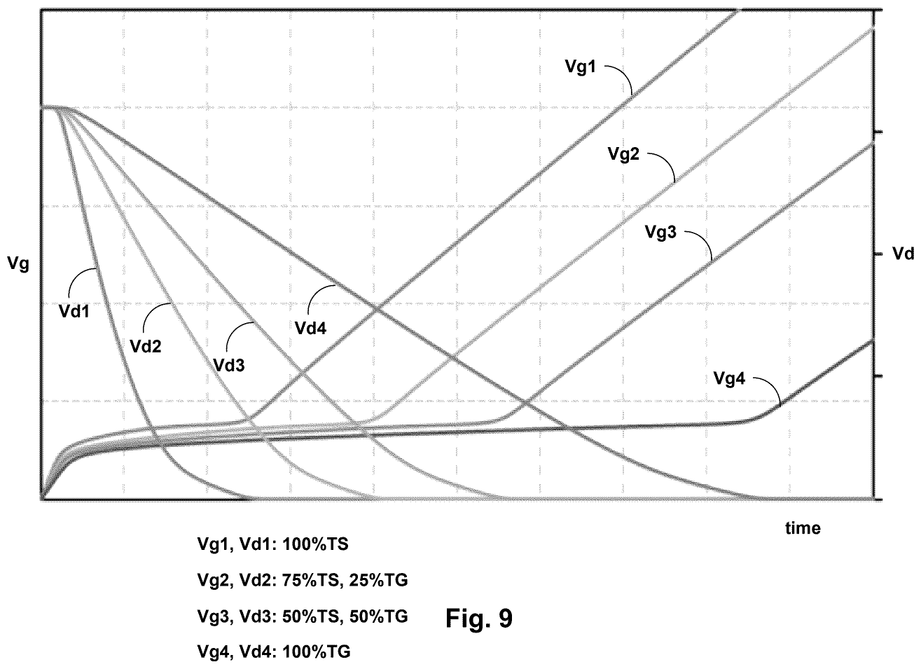

FIG. 7 is a cross-sectional schematic diagram of a tie-source high-side switch device according to an embodiment of the present invention. As shown in FIG. 7, in addition to the semiconductor layer 41, the first high-voltage well region 45, the isolation region 49, the body region 50, the body contact 51, the gate 52, the resist protection oxide region 53, the source 55, the drain 56, and the independent connection channel 60 shown in FIG. 4, the tie-source high-side switch device 40 also includes, for example, a first deep well region 44, second high-voltage well regions 46 and 47, a second deep well region 43, a buried layer 42, a third high-voltage well region 48, and electrical contact regions 57, 58, and 59. Except for the independent connection channel 60, the tie-source high-side switch device 40 shown in FIG. 7 is structurally identical to the tie-gate high-side switch device 10 shown in FIG. 6, and thus will not be further described. The independent connection channel 60 is formed to connect the split gate 54 and the source 55 to electrically connect the split gate 54 to the source 55. Each tie-source high-side switch device 40 includes its own independent connection channel 60, which is not shared with other tie-source high-side switch devices 40. The independent connection channel 60 may be formed by process steps of forming plugs and metal lines, which are well-known to those skilled in the art and are not further detailed here.

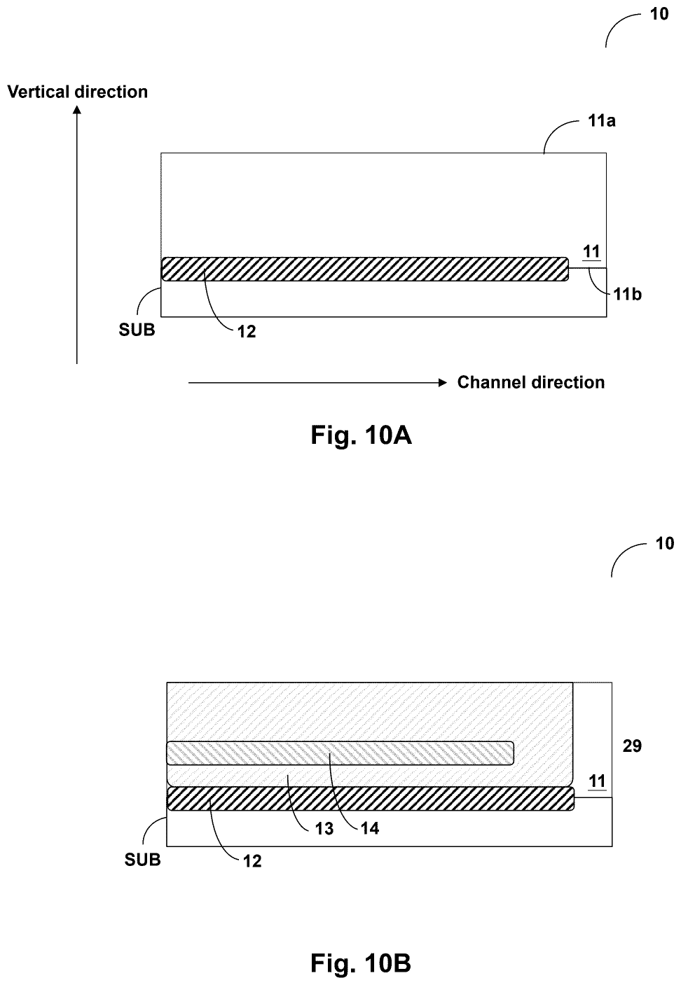

FIG. 8 shows signal waveforms of the phase node voltage Vsw at different ratios of tie-gate high-side switch devices to tie-source high-side switch devices. As shown in FIG. 8, the solid black line indicates the signal waveform when the finger structure of the high-side switch device having split gates is composed of 100% tie-source high-side switch devices 40. Under this condition, the ringing peak voltage and overshoot voltage of the phase node voltage Vsw are the highest, and the equivalent charge is, for example, 100*Qg. The solid gray line indicates the signal waveform when the finger structure of the high-side switch device having split gates is composed of 75% tie-source high-side switch devices 40 and 25% tie-gate high-side switch devices 10. Under this condition, the ringing peak voltage and overshoot voltage of the phase node voltage Vsw are the second highest, and the equivalent charge is, for example, 125*Qg. The dashed black line indicates the signal waveform when the finger structure of the high-side switch device having split gates is composed of 50% tie-source high-side switch devices 40 and 50% tie-gate high-side switch devices 10. Under this condition, the ringing peak voltage and overshoot voltage of the phase node voltage Vsw are lower, and the equivalent charge is, for example, 150*Qg. The dashed gray line indicates the signal waveform when the finger structure of the high-side switch device having split gates is composed of 100% tie-gate high-side switch devices 10. Under this condition, the ringing peak voltage and overshoot voltage of the phase node voltage Vsw are the lowest, and the equivalent charge is, for example, 200*Qg.

A larger equivalent charge Qg significantly reduces the ringing peak voltage and overshoot voltage of the phase node voltage Vsw. However, this will result in a longer rise time, which may also lead to greater power loss. By appropriately selecting the layout and the ratio of the number of tie-gate high-side switch devices 10 to the number of tie-source high-side switch devices 40, it is possible to reduce the ringing peak voltage and overshoot voltage of the phase node voltage Vsw while achieving faster switching speed, thereby maintaining a high switching speed while minimizing the ringing peak voltage and overshoot voltage.

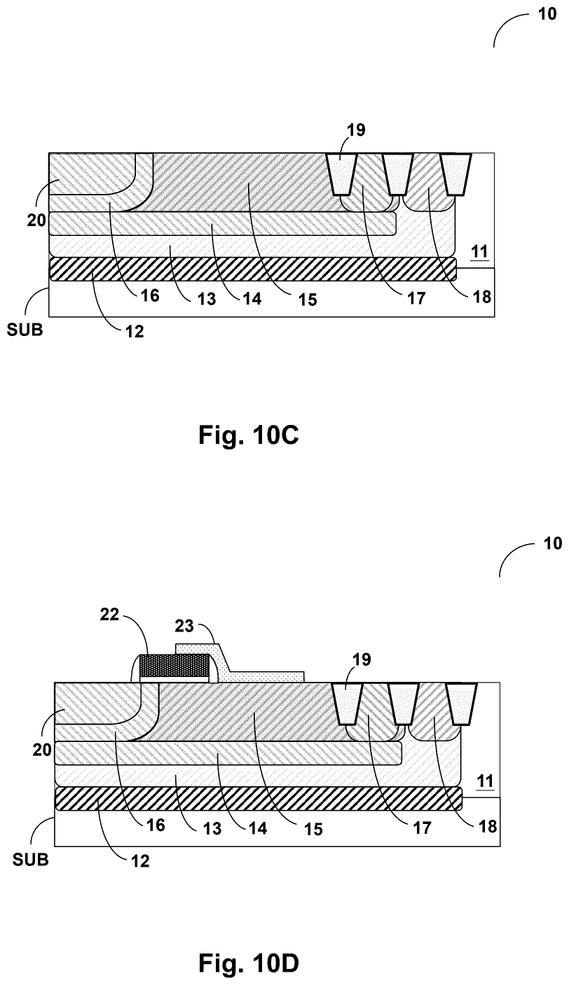

FIG. 9 shows signal waveforms of the gate voltage Vg and the drain voltage Vd at different ratios of tie-gate high-side switch devices to tie-source high-side switch devices. As shown in FIG. 9, under the condition where 100% of the devices are tie-source high-side switch devices 40, the change in gate voltage Vg1 and drain voltage Vd1 is the fastest. Under the condition where 75% of the devices are tie-source high-side switch devices 40 and 25% are tie-gate high-side switch devices 10, the change in gate voltage Vg2 and drain voltage Vd2 is the second fastest. Under the condition where 50% of the devices are tie-source high-side switch devices 40 and 50% are tie-gate high-side switch devices 10, the change in gate voltage Vg3 and drain voltage Vd3 is slower. Under the condition where 100% of the devices are tie-gate high-side switch devices 10, the change in gate voltage Vg4 and drain voltage Vd4 is the slowest.

In other words, under the condition where 100% of the devices are tie-source high-side switch devices 40, the switching speed is the fastest, but the ringing voltage of the phase node voltage Vsw is also the highest. Under the condition where 100% of the devices are tie-gate high-side switch devices 10, the switching speed is the slowest, but the ringing voltage of the phase node voltage Vsw is also the lowest. According to the present invention, the ratio of the number of tie-gate high-side switch devices 10 to the number of tie-source high-side switch devices 40 is adjusted based on the ringing voltage and switching speed of the phase node voltage Vsw during normal operation, and further adjusted based on the power conversion efficiency during normal operation, to achieve the optimal switching speed and acceptable ringing voltage while maintaining optimized power conversion efficiency.

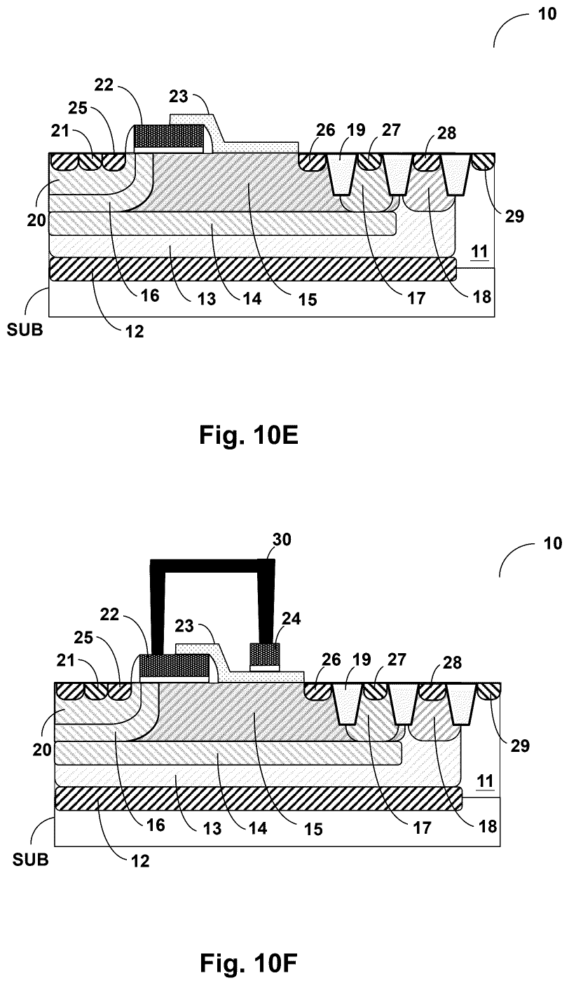

Please refer to FIGS. 10A-10F, which are cross-sectional schematic diagrams showing the manufacturing method of a tie-gate high-side switch device 10 according to an embodiment of the present invention. Except for the independent connection channel, the tie-source high-side switch device 40 and the tie-gate high-side switch device 10 are structurally identical, and the manufacturing method is also the same, so they can be inferred. Furthermore, the manufacturing method of a high-side switch device having split gates includes forming at least one tie-gate high-side switch device, each having a split gate independently connected to a corresponding gate, and forming at least one tie-source high-side switch device, each having a split gate independently connected to a corresponding source, wherein the at least one tie-gate high-side switch device and the at least one tie-source high-side switch device are connected in parallel, and the ratio of the number of tie-gate high-side switch devices to the number of tie-source high-side switch devices can be selected to adjust the Miller capacitance of the high-side switch device having split gates. Therefore, the manufacturing method of the high-side switch device having split gates can also be inferred from this embodiment.

As shown in FIG. 10A, a substrate SUB is first provided, and a semiconductor layer 11 is formed on the substrate SUB. A buried layer 12 is formed on both sides of the interface between the substrate SUB and the semiconductor layer 11, with portions of the buried layer 12 located in the substrate SUB and portions located in the semiconductor layer 11. The substrate SUB may be, but is not limited to, a P-type or N-type semiconductor substrate. The semiconductor layer 11 has a top surface 11a and a bottom surface 11b opposite to the top surface 11a in the vertical direction.

Next, as shown in FIG. 10B, a second deep well region 13 of the first conductivity type is formed in the semiconductor layer 11. For example, an ion implantation process is used to implant impurities of the first conductivity type (N-type or P-type) into the semiconductor layer 11 in the form of accelerated ions, which is well-known to those skilled in the art and is not further detailed here.

Next, referring to FIG. 10C, a first deep well region 14, a first high-voltage well region 15, second high-voltage well regions 16 and 17, a third high-voltage well region 18, an isolation region 19, and a body region 20 are formed. The first deep well region 14, the second high-voltage well regions 16 and 17, and the body region 20 are formed, for example, by ion implantation, where impurities of the second conductivity type are implanted into the semiconductor layer 11 in the form of accelerated ions. The first high-voltage well region 15 and the third high-voltage well region 18 are formed, for example, by ion implantation, where impurities of the first conductivity type are implanted into the semiconductor layer 11 in the form of accelerated ions. The isolation region 19 is formed in the semiconductor layer 11 to electrically isolate the tie-gate high-side switch device from adjacent devices. The isolation region 19 may be, but is not limited to, a shallow trench isolation (STI) structure as shown in FIG. 10C.

Next, referring to FIG. 10D, a gate 22 and a resist protection oxide region 23 are formed and connected to the top surface 11a, located above the drift region.

Next, referring to FIG. 10E, a body contact 21, a source 25, a drain 26, and electrical contact regions 27, 28, and 29 are formed. The source 25, the drain 26, and the electrical contact region 28 are formed, for example, by ion implantation, where impurities of the first conductivity type are implanted into the semiconductor layer 11 in the form of accelerated ions. The body contact 21 and the electrical contact regions 27 and 29 are formed, for example, by ion implantation, where impurities of the second conductivity type are implanted into the semiconductor layer 11 in the form of accelerated ions. The body contact 21 is formed beneath and connected to the top surface 11a, located in the body region 20, serving as the electrical contact for the body region 20. In this embodiment, the body contact 21 is connected to the source 25, sharing the same potential.

Next, referring to FIG. 10F, the independent connection channel 30 is formed and connected above the split gate 24 and the gate 22 to electrically connect the split gate 24 to the gate 22. Each tie-gate high-side switch device 10 includes its own independent connection channel 30, which is not shared with other tie-gate high-side switch devices 10. The independent connection channel 30 may be formed by process steps of forming plugs and metal lines, which are well-known to those skilled in the art and are not further detailed here.

The second deep well region 13 of the first conductivity type is formed in the semiconductor layer 11 and connected below the first deep well region 14 in the vertical direction. The first high-voltage well region 15 of the first conductivity type is located below and connected to the top surface 11a in the vertical direction. The body region 20 of the second conductivity type is formed in the first high-voltage well region 15, located below and connected to the top surface 11a in the vertical direction.

The gate 22 is formed on the top surface 11a of the semiconductor layer 11. In the vertical direction, a portion of the body region 20 is directly beneath and connected to the gate 22 to provide an inversion current path during the conductive operation of the tie-gate high-side switch device 10. The resist protection oxide region 23 is formed on the top surface 11a, with a portion connected to the top surface 11a and located above the drift region. The split gate 24 is formed on the resist protection oxide region 23 and arranged parallel to the gate 22 in the width direction (as schematically shown in FIG. 2). The source 25 and drain 26 of the first conductivity type are formed beneath the top surface 11a and connected to the top surface 11a in the vertical direction. The source 25 is located in the body region 20 under an outer side of the gate 22, while the drain 26 is located in the first high-voltage well region 15 under another outer side of the gate 22 remote from the body region 20. In the channel direction, the drift region is located between the drain 26 and the body region 20, close to the top surface 11a in the first high-voltage well region 15, serving as a drift current path during the conductive operation of the tie-gate high-side switch device 10.

The present invention has been described in considerable detail with reference to certain preferred embodiments thereof. It should be understood that the description is for illustrative purpose, not for limiting the broadest scope of the present invention. Those skilled in this art can readily conceive variations and modifications within the spirit of the present invention. The various embodiments described above are not limited to being used alone; two embodiments may be used in combination, or a part of one embodiment may be used in another embodiment. For example, other process steps or structures, such as a deep well region, may be added. For another example, the lithography process step is not limited to the mask technology but it can also include electron beam lithography, immersion lithography, etc. Therefore, in the same spirit of the present invention, those skilled in the art can think of various equivalent variations and various combinations, and there are many combinations thereof, and the description will not be repeated here. The scope of the present invention should include what are defined in the claims and the equivalents.

What is claimed is:

1. A high-side switch device having split gates, comprising:
at least one tie-gate high-side switch device, each having a split gate independently connected to a corresponding gate; and
at least one tie-source high-side switch device, each having a split gate independently connected to a corresponding source;
wherein the at least one tie-gate high-side switch device and the at least one tie-source high-side switch device are electrically connected in parallel;
wherein a ratio of a quantity of the at least one tie-gate high-side switch device to a quantity of the at least one tie-source high-side switch device is selectable to adjust a Miller capacitance of the high-side switch device having split gates.

2. The high-side switch device having split gates of claim 1, wherein the ratio of the quantity of the at least one tie-gate high-side switch device to the quantity of the at least one tie-source high-side switch device is adjusted according to a peak voltage of a ringing at a phase node and a switching speed during a normal operation.

3. The high-side switch device having split gates of claim 2, wherein the ratio of the quantity of the at least one tie-gate high-side switch device to the quantity of the at least one tie-source high-side switch device is further adjusted according to a power conversion efficiency during the normal operation.

4. The high-side switch device having split gates of claim 1, wherein each of the at least one tie-gate high-side switch device or each of the at least one tie-source high-side switch device includes:
a semiconductor layer formed on a substrate and having a top surface and a bottom surface opposite to the top surface in a vertical direction;
a first high-voltage well region of a first conductivity type formed in the semiconductor layer and connected to the top surface in the vertical direction;
a body region of a second conductivity type formed in the first high-voltage well region and connected to the top surface in the vertical direction;
the gate formed on the top surface of the semiconductor layer, wherein a portion of the body region is located right below and in contact with the gate in the vertical direction to provide an inversion current path in a conductive operation of the tie-gate high-side switch device or the tie-source high-side switch device;
a resist protection oxide (RPO) region formed on the top surface, with a portion of the resist protection oxide region being connected to the top surface and located above a drift region;
the split gate formed on the resist protection oxide region and arranged parallel to the gate in a width direction; and
a source and a drain of the first conductivity type formed in the semiconductor layer beneath and in contact with the top surface, wherein the source is located in the body region under an outer side of the gate and the drain is located in the first high-voltage well region under another outer side of the gate remote from the body region, wherein the drift region is located between the drain and the body region in a channel direction and located in the first high-voltage well region close to the top surface to serve as a drift current path in the conductive operation of the tie-gate high-side switch device or the tie-source high-side switch device.

5. The high-side switch device having split gates of claim 4, wherein each of the at least one tie-gate high-side switch device or each of the at least one tie-source high-side switch device further includes:
a first deep well region of the second conductivity type formed in the semiconductor layer and located beneath and in contact with the first high-voltage well region in the vertical direction;
a second deep well region of the first conductivity type formed in the semiconductor layer and located beneath and in contact with the first deep well region in the vertical direction; and
a buried layer of the first conductivity type formed beneath the second deep well region and connected to the second deep well region in the vertical direction, the buried layer entirely covering an underside of the second deep well region, with portions of the buried layer being located in the substrate and in the semiconductor layer on both sides of an interface between the substrate and the semiconductor layer in the vertical direction;
wherein the first deep well region is located between the first high-voltage well region and the second deep well region in the vertical direction, forming a complete isolation structure during a normal operation.

6. A manufacturing method of a high-side switch device having split gates, comprising:
forming at least one tie-gate high-side switch device, each having a split gate independently connected to a corresponding gate; and
forming at least one tie-source high-side switch device, each having a split gate independently connected to a corresponding source;
wherein the at least one tie-gate high-side switch device and the at least one tie-source high-side switch device are electrically connected in parallel;
wherein a ratio of a quantity of the at least one tie-gate high-side switch device to a quantity of the at least one tie-source high-side switch device is selectable to adjust a Miller capacitance of the high-side switch device having split gates.

7. The manufacturing method of claim 6, wherein the ratio of the quantity of the at least one tie-gate high-side switch device to the quantity of the at least one tie-source high-side switch device is adjusted according to a peak voltage of a ringing at a phase node and a switching speed during a normal operation.

8. The manufacturing method of claim 7, wherein the ratio of the quantity of the at least one tie-gate high-side switch device to the quantity of the at least one tie-source high-side switch device is further adjusted according to a power conversion efficiency during the normal operation.

9. The manufacturing method of claim 6, wherein the step of forming each of the at least one tie-gate high-side switch device or each of the at least one tie-source high-side switch device includes:
forming a semiconductor layer on a substrate, the semiconductor layer having a top surface and a bottom surface opposite to the top surface in a vertical direction;
forming a first high-voltage well region in the semiconductor layer, the first high-voltage well region having a first conductivity type, and being connected to the top surface in the vertical direction;
forming a body region in the first high-voltage well region, the body region having a second conductivity type, and being connected to the top surface in the vertical direction;
forming the gate on the top surface of the semiconductor layer, wherein a portion of the body region is located right below and in contact with the gate in the vertical direction to provide an inversion current path in a conductive operation of the tie-gate high-side switch device or the tie-source high-side switch device;
forming a resist protection oxide (RPO) region on the top surface, with a portion of the resist protection oxide region being connected to the top surface and located above a drift region;
forming the split gate on the resist protection oxide region, with the split gate arranged parallel to the gate in a width direction; and
forming a source and a drain beneath and in contact with the top surface in the semiconductor layer, the source and the drain having the first conductivity type, wherein the source is located in the body region under an outer side of the gate and the drain is located in the first high-voltage well region under another outer side of the gate remote from the body region, wherein the drift region is located between the drain and the body region in a channel direction and located in the first high-voltage well region close to the top surface to serve as a drift current path in the conductive operation of the tie-gate high-side switch device or the tie-source high-side switch device.

10. The manufacturing method of claim 9, wherein the step of forming each of the at least one tie-gate high-side switch device or the at least one tie-source high-side switch device further comprises:
forming a first deep well region in the semiconductor layer, the first deep well region having the second conductivity type, and being located beneath and in contact with the first high-voltage well region in the vertical direction;
forming a second deep well region in the semiconductor layer, the second deep well region having the first conductivity type, and being located beneath and in contact with the first deep well region in the vertical direction; and
forming a buried layer beneath the second deep well region, the buried layer having the first conductivity type, and being connected to the second deep well region in the vertical direction, the buried layer entirely covering an underside of the second deep well region, with portions of the buried layer being located in the substrate and in the semiconductor layer on both sides of an interface between the substrate and the semiconductor layer in the vertical direction;
wherein the first deep well region is located between the first high-voltage well region and the second deep well region in the vertical direction, forming a complete isolation structure during a normal operation.
